(19) United States
(12) Patent Application Publication
(10) Pub. No.: US 2025/0096097 A1
(43) Pub. Date: Mar. 20, 2025

(54) SEMICONDUCTOR PACKAGE AND METHOD FOR MANUFACTURING SAME

(71) Applicant: HANA MICRON INC., Asan-si (KR)

(72) Inventors: Jae-Sung LIM, Seongnam-si (KR); Donghyun KIM, Seongnam-si (KR)

(21) Appl. No.: 18/471,246

(22) Filed: Sep. 20, 2023

(51) Int. Cl. H01L 23/498; H01L 21/683; H01L 21/768; H01L 23/00; H01L 23/31; H01L 23/367; H01L 25/065

(52) U.S. Cl. CPC H01L 23/49838; H01L 21/6835; H01L 21/768; H01L 23/3128; H01L 23/3672; H01L 23/49827; H01L 24/13; H01L 24/16; H01L 24/32; H01L 25/0652; H01L 2224/13017; H01L 2224/13023; H01L 2224/16113; H01L 2224/16195; H01L 2224/16235

(57) ABSTRACT

Disclosed is a semiconductor package and a method for manufacturing the same, wherein manufacturing costs and manufacturing processes may be further reduced. The semiconductor package includes, a first die, a second die arranged horizontally to the first die, a printed circuit board (PCB) layer including circuit and a PCB pillar extending upwards from the circuit so as to abut the first die or the second die, and a connecting structure disposed on an upper surface of the PCB layer between two different PCB pillars and conductively connected to each of the first die and the second die.

### BACKGROUND OF THE INVENTION

### 1. Field of the Invention

The present disclosure relates to a semiconductor package and a method for manufacturing the same and, more particularly, to a semiconductor package and a method for manufacturing the same, wherein manufacturing costs and manufacturing processes can be further reduced.

### 2. Description of the Prior Art

A semiconductor chip refers to an integrated circuit made of a semiconductor having an electrical conductivity higher than that of a nonconductor and lower than that of a conductor. In general, a type of packaging operation is necessary after separating semiconductor chips from a monocrystalline substrate (wafer). This is for the purpose of protecting semiconductor chips from physical impacts and alleviating the difference in degree of integration from the substrate on which semiconductor chips are to be mounted, thereby increasing mounting convenience.

The result of packaging semiconductor chips is referred to as a semiconductor package.

Multiple semiconductor chips may be mounted on semiconductor packages, which may be classified into 2D/2.5D/3D and the like according to the arrangement of semiconductor chips mounted thereon. Among the same, a 2.5D semiconductor package refers to a packaging scheme in which logic chips are arranged horizontally, and memory chips are stacked vertically.

Such a 2.5D semiconductor package may have interposers between the substrate and the die in order to increase the ratio of connection between the substrate and the semiconductor chips. In this case, semiconductor chips are electrically connected to the substrate through interposers.

However, there is a problem in that interposers have somewhat high material costs and are disadvantageous in terms of semiconductor package compactness. Therefore, development of a semiconductor package and a method for manufacturing the same with reduced manufacturing costs may be considered.

Korean Registered Patent Publication No. 10-2206937 discloses a semiconductor package interposer and, particularly, discloses a semiconductor package interposer which can be formed in an ultra-thin shape.

However, such a type of interposer does not disclose any specific coupling relation with and the substrate or semiconductor chips, and does not disclose any structure for reducing material costs of the interposer or for making the same compact.

Korean Registered Patent Publication No. 10-2020-0132511 discloses an interposer substrate and a semiconductor package including the same and, particularly, discloses an interposer substrate configured such that the process yield can be increased, and the problem of warpage or misalignment can be solved.

However, such a type of interposer is aimed at increasing the area thereof, and is disadvantageous in terms of material costs and compactness.

### SUMMARY OF THE INVENTION

An aspect of the present disclosure is to provide a semiconductor package and a method for manufacturing same, wherein manufacturing costs can be further reduced.

Another aspect of the present disclosure is to provide a semiconductor package and a method for manufacturing same, wherein a high-performance semiconductor package can be made compact.

Another aspect of the present disclosure is to provide a semiconductor package and a method for manufacturing same, wherein manufacturing processes can be further simplified.

Another aspect of the present disclosure is to provide a semiconductor package and a method for manufacturing same, wherein semiconductor chips mounted therein can be prevented from overheating.

In accordance with an aspect of the present disclosure, a semiconductor package includes: a first die; a second die arranged horizontally to the first die; a printed circuit board (PCB) layer including a circuit and a PCB pillar extending upwards from the circuit so as to abut the first die or the second die; and a connecting structure disposed on an upper surface of the PCB layer between two different PCB pillars and conductively connected to each of the first die and the second die.

In addition, a connecting pillar may be formed on an upper surface of the connecting structure so as to extend upwards with an increasing horizontal width and to abut the first die or the second die.

In addition, the connecting structure may have a sectional area formed to be smaller than the combined sectional area of the first die and the second die coupled to the connecting structure.

In addition, the sum of the height H2 of the connecting structure and the height H1 of the connecting pillar formed on the connecting structure may be formed to be smaller than the sum of the horizontal thickness of the PCB pillars and the interval between two PCB pillars adjacent to each other horizontally.

In addition, the height H1 of the connecting pillar formed on the connecting structure may be formed to be smaller than the sum of the horizontal thickness of the connecting pillar and the interval between two connecting pillars adjacent to each other horizontally.

In addition, the height of the connecting pillar may be formed within to 50-150% of the height of the connecting structure.

In addition, a connecting pillar may be formed on an upper surface of the connecting structure so as to extend upwards and to abut the first die or the second die, and the connecting pillar and the PCB pillar may have respective upper ends positioned on a straight line horizontally.

In addition, multiple second dies may be arranged side by side horizontally, and the connecting structure may have at least a part conductively connected to each of multiple different second dies.

In addition, the semiconductor package may further include a heat dissipation die or an active die vertically overlapping at least two second dies.

In addition, the semiconductor package may further a thermal interface material between the second die and the heat dissipation die or the active die and on upper surfaces of the first die and the heat dissipation die or the active die, respectively, so as to dissipate heat generated in the second die outwards. Herein, the active die may comprise an electric connecting means provided on a lower portion thereof so as to be connected to the second die.

In addition, multiple first dies may be formed to be vertically stacked.

In addition, the connecting structure may be made of a silicon wafer.

In addition, the connecting structure may be made of an active die or an integrated passive device (IPD).

In addition, multiple external connection members may be disposed on the lower surface of the PCB layer so as to be spaced apart from each other.

Multiple PCB pillars and connecting pillars formed on the upper surface of the connecting structure may be disposed on an upper surface of the PCB layer to be spaced apart from each other. The PCB pillars and the connecting pillars may be formed at an identical height. Assuming that the PCB layer has a transverse length of Lx and has a longitudinal length of Ly, the PCB pillars and connecting pillars have transverse coordinates of xi and have longitudinal coordinates of yi, and the pad area of connecting pillars or PCB pillars formed on the PCB layer and exposed is Ai, equations

$$\frac{1}{3} {L}_{x} < \frac{Σ {x}_{i} {A}_{i}}{Σ {A}_{i}} < \frac{2}{3} {L}_{x} and \frac{1}{3} {L}_{y} < \frac{Σ {y}_{i} {A}_{i}}{Σ {A}_{i}} < \frac{2}{3} {L}_{y}$$

may be both satisfied.

In accordance with another aspect of the present disclosure, a semiconductor package manufacturing method includes the steps of: (a) forming a PCB pillar so as to extend upwards from a circuit of a PCB layer; (b) installing a connecting structure between two different PCB pillars; (c) forming a mold on the PCB layer and the connecting structure; (d) grinding the mold such that the upper end of the PCB pillar and the upper end of a connecting pillar extending upwards from the connecting structure are exposed outwards; and (e) installing a first die and a second die side by side horizontally on the upper end of the PCB layer and on the upper end of the connecting pillar such that each of the first die and the second die contact the connecting pillar conductively.

In addition, prior to step (b), a step (b0) of forming the connecting pillar on the upper surface of the connecting structure so as to extend upwards with an increasing horizontal width may be performed.

In addition, after step (d) and prior to step (e), a step (e0) of coupling a release layer 2 and a carrier substrate to the lower surface of the PCB layer may be performed, and after step (e), a step (e1) of removing the release layer 2 and the carrier substrate may be performed.

In addition, after step (e), a step (f) of applying an external connection member to the lower surface of the PCB layer may be performed.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a conceptual diagram illustrating a semiconductor package according to an embodiment of the present disclosure;

FIG. 2 is a conceptual diagram illustrating a second die, a PCB layer, a connecting structure, and an attachment member included in the semiconductor package in FIG. 1;

FIG. 3 is a top view of a PCB layer included in the semiconductor package in FIG. 1, and a PCB pillar formed on the PCB layer, and a connecting pillar,

FIG. 4 illustrates a PCB layer included in the semiconductor package in FIG. 1, a second die disposed above the PCB layer, and a PCB pillar and a connecting structure disposed between the PCB layer and the second die;

FIG. 5 is a conceptual diagram illustrating a connecting structure included in the semiconductor package in FIG. 1;

FIG. 6 is a conceptual diagram illustrating a PCB pillar formed on a PCB layer, and a connecting structure;

FIG. 7 is a conceptual diagram illustrating a PCB layer included in the semiconductor package in FIG. 1;

FIG. 8 is a conceptual diagram illustrating a PCB layer having a connecting structure installed thereon;

FIG. 9 is a conceptual diagram illustrating a connecting structure and a PCB layer coupled to a mold;

FIG. 10 is a conceptual diagram illustrating a connecting structure a PCB layer coupled to a second die; and

FIG. 11 is a conceptual diagram illustrating a PCB layer coupled to an attachment member, a connecting structure, and a second die.

### DETAILED DESCRIPTION OF THE EXEMPLARY EMBODIMENTS

Hereinafter, a semiconductor package 1 according to an embodiment of the present disclosure will be described in more detail with reference to the accompanying drawings.

In the following description, descriptions of some components may be omitted to clarify features of the present disclosure.

In the present specification, identical reference numerals will be assigned to identical components even in different embodiments, and repeated descriptions thereof will be omitted.

The accompanying drawings are only for helping understanding of embodiment disclosed in the present specification, and do not limit the technical idea disclosed in the present specification.

Expressions in singular forms include expressions in plural forms unless explicitly specified otherwise.

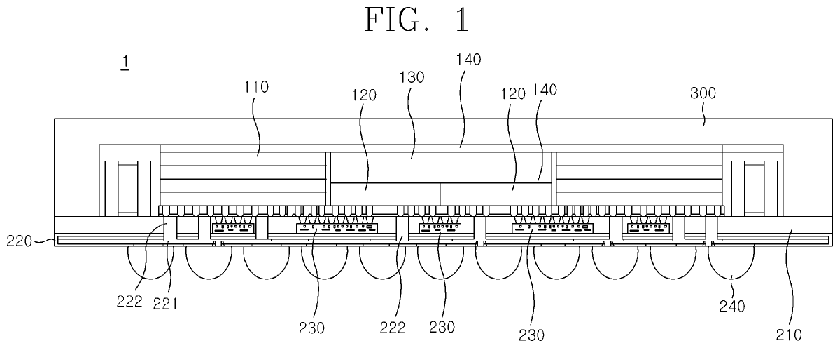

Hereinafter, a semiconductor package 1 according to an embodiment of the present disclosure will be described with reference to FIG. 1 to FIG. 5.

The semiconductor package 1 refers to the result of packaging a second die 120.

The semiconductor package 1 protects the second die 120 from physical impacts, and alleviates the difference in degree of integration with the substrate to which the second die 120 is to be mounted, thereby increasing mounting convenience.

Multiple dies or a second die 120 is mounted inside the semiconductor package 1. The multiple dies or second die 120 may be arranged vertically or horizontally. In addition, vertically arranged multiple dies and a horizontally arranged second die 120 may be mixed and disposed.

In the illustrated embodiment, the semiconductor package 1 includes a first die 110, a second die 120, a heat dissipation die 130, a thermal interface material 140, a mold 210, a PCB layer 220, a connecting structure 230, an external connection member 240, and a protective member 300.

A single first die 110 or multiple first dies 110 may be included. In an embodiment, multiple dies are formed to be stacked vertically.

In an embodiment, the first die 110 may be made of a memory chip.

The first die 101 is arranged horizontally arranged in parallel to the second die 120.

The second die 120 is made of an integrated circuit made of a semiconductor having an electrical conductivity higher than that of a nonconductor and lower than that of a conductor.

The second die 120 is arranged horizontally to the first die 110.

In an embodiment, multiple second dies 120 may be included. In the illustrated embodiment, multiple second dies 120 are included. In the above-mentioned embodiment, multiple second dies 120 are horizontally arranged side by side.

In an embodiment, the second die 120 may be made of a semiconductor IC or a logic chip.

A heat dissipation die 130 or an active die may be stacked above the second die 120 and, if an active die is stacked, electrical connection to the second die may be additionally configured. In this case, the active die may comprise an electric connecting means provided on a lower portion thereof so as to be connected to the second die.

The heat dissipation die 130 vertically overlaps at least two second dies 120.

In the illustrated embodiment, each of the lower and upper surfaces of the heat dissipation die 130 is coupled to a thermal interface material 140.

The thermal interface material (TIM) 140 dissipates heat generated by the second die 120 to the outside. To this end, the thermal interface material 140 is preferably made of a material having a high level of thermal conductivity.

In an embodiment, the thermal interface material 140 may be disposed between the second die 120 and the heat dissipation die 130. In another embodiment, the thermal interface material 140 may be disposed on the upper surface of the heat dissipation die 130. In another embodiment, the thermal interface material 140 may be disposed on the upper surface of the first die 110 and on the upper surface of the heat dissipation die 130.

However, the thermal interface material 140 is not limited to the above-mentioned embodiment, and may be formed in various structures. For example, the thermal interface material 140 may be disposed between the second die 120 and the heat dissipation die 130, on the upper surface of the first die 110, and on the upper surface of the heat dissipation die 130, respectively.

Therefore, heat generated in the second die 120 may be dissipated more easily, thereby preventing the second die 120 from overheating. Moreover, any damage to the semiconductor package 1 due to overheating may be prevented, and maintenance/repair costs incurred by such damage occurring may be avoided.

The upper side and side surfaces of the first die 110, the heat dissipation die 130, the second die 120, and the thermal interface material 140 are surrounded by a protective member 300.

The protective member 300 protects components mounted therein from physical impacts. In addition, the protective member 300 assists in retention between the first die 110, the second die 120, the heat dissipation die 130, and the thermal interface material 140, thereby preventing them from escaping inadvertently.

Considering such points, the protective member 300 is preferably formed in a shape corresponding to a structure coupled to the first die 110, the second die 120, the heat dissipation die 130, and the thermal interface material 140.

In an embodiment, the protective member 300 may be made of a steel can material.

The PCB layer 220 and the connecting structure 230 (described later) are protected by the mold 210, and retention between respective components is assisted by the mold 210.

The printed circuit board (PCB) layer 220 is provided beneath the first die 110 and the second die 120.

The PCB layer 220 may be provided with electric components such as integrated circuits, resistors, or switches.

In an embodiment, the PCB layer 220 may be made of an organic PCB.

In the illustrated embodiment, the PCB layer 220 includes a circuit 221 and a PCB pillar 222 formed above the circuit 221.

The PCB pillar 222 is disposed to abut the first die 110 or the second die 120 and is electrically connected to the first die 110 or the second die 120. Accordingly, the circuit 221 of the PCB layer 220 may also be electrically connected to the first die 110 or the second die 120.

The PCB pillar 222 is formed to extend upwards from the circuit 221. In an embodiment, the PCB pillar 222 may be formed so as to extend upwards with an increasing horizontal width and to abut the first die or the second die.

The PCB pillar 222 may have an upper end formed by a grinding process.

Multiple PCB pillars 222 are formed.

A connecting structure 230 may be installed between two different PCB pillars 222.

The connecting structure 230 aims at electric connection between the first die 110 and the second die 120 or between multiple different second dies 120.

The connecting structure 230 is disposed on the upper surface of the PCB layer 220. In addition, the connecting structure 230 is installed between two different PCB pillars 222.

The upper end of the connecting structure 230 abuts the first die 110 or the second die 120. In an embodiment, upper end of the connecting structure 230 abuts each of the first die 110 and the second die 120. In another embodiment, upper end of the connecting structure 230 abuts each of two different second dies 120.

In addition, the connecting structure 230 is connected conductively to the first die 110 or the second die 120 which abuts the connecting structure 230.

The connecting structure 230 is not necessarily installed on the entire surface of the PCB layer 220, but is sufficiently installed on a part of the upper surface of the PCB layer 220 overlapping the first die 110 and the second die 120. In the illustrated embodiment, the connecting structure 230 is formed to have a sectional area smaller than the combined sectional area of the first die 110 and the second die 120 coupled to the connecting structure 230.

This may reduce the area of installation of the connecting structure 230, thereby decreasing the manufacturing cost of the connecting structure 230. Furthermore, the entire cost for manufacturing the semiconductor package 1 may be decreased.

In addition, the reduced area of installation of the connecting structure 230, as described above, is advantageous for compactness of the connecting structure 230.

Therefore, as the connecting structure 230 occupies a reduced space, it may become possible to implement the entire high-performance semiconductor package 1 compact.

In an embodiment, the connecting structure 230 may be made of a silicon wafer.

In another embodiment, the connecting structure 230 may be made of an active die or an integrated passive device (IPD).

An external connection member 240 may be provided on the lower surface of the PCB layer 220.

The external connection member 240 may play the role of electrically connecting the PCB layer 220 and the semiconductor package 1 to an external member.

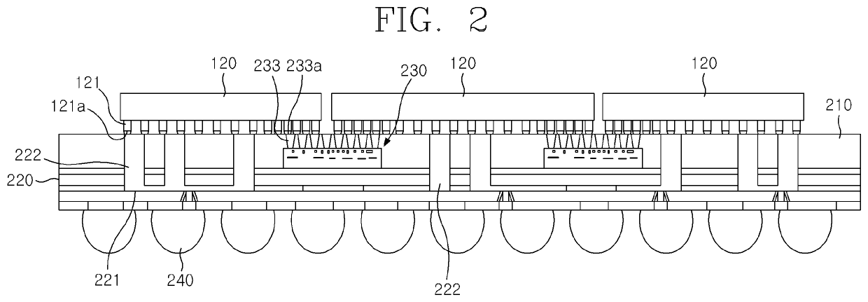

Hereinafter, electric connection between the second die 120 and the PCB layer 220 or the connecting structure 230 will be described with reference to FIG. 2.

A chip connection member 121 is formed downwards on the lower surface of the second die 120 for electric connection to the PCB layer 220. In addition, a chip connection portion 121a may be additionally formed on the lower surface of the chip connection member 121. The chip connection member 121 may have an upper end formed by a grinding process.

As described above, a PCB pillar 222 is formed on the upper surface of the PCB layer 220 and is disposed to abut the first die 110 or the second die 120. The PCB pillar 222 which abuts the second die 120 is disposed to abut the chip connection portion 121a. Accordingly, the second die 120 and the PCB layer 220 may be electrically connected to each other.

In addition, the second die 120 and the PCB layer 220 may have an additional electric connection passage provided by the connecting structure 230.

In the illustrated embodiment, the connecting structure 230 has a connecting pillar 233 has a connecting pillar 233 formed on the upper surface thereof so as to extend upwards.

The connecting pillar 233 is made of an electrically conductive material. For example, the connecting pillar 233 may be made of a metal material such as copper (Cu).

Although it has been assumed in the above description that the connecting structure 230 abuts two different second dies 120, the above description is not limited to the above embodiment, and is also applicable to a connecting structure 230 abutting each of the first die 110 and the second die 120.

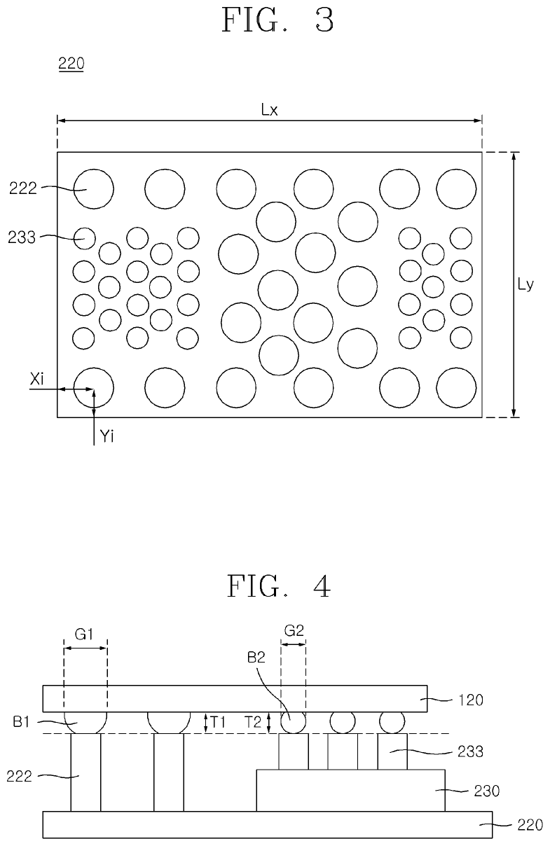

Hereinafter, the PCB pillar 222 and the connecting pillar 233 of the connecting structure 230 formed on the upper surface of the PCB layer 220 will be described in more detail with reference to FIG. 3.

Multiple PCB pillars 222 and connecting pillars 233 may be disposed on the upper surface of the PCB layer 220 to be spaced apart from each other.

The diameter of the PCB pillars 222 may be larger than that of the connecting pillars 233, and the interval between multiple PCB pillars 222 may be larger than that between pillars of the connecting structure.

The dense total area of the connecting pillars 233 and different total areas of the PCB pillars 222 are formed to differ from each other.

Multiple PCB pillars 222 and the connecting pillars 233 are formed to have constant heights. Assuming that the transverse length of the PCB layer is Lx, the longitudinal length there of is Ly, the transverse coordinates of the PCB pillars 222 and connecting pillars 223 are xi, the longitudinal coordinates thereof are yi, and the pad area of PCB pillars 222 or connecting pillars 233 formed on the PCB layer 220 and exposed is Ai, the following equations may be satisfied:

$$\frac{1}{3} {L}_{x} < \frac{Σ {x}_{i} {A}_{i}}{Σ {A}_{i}} < \frac{2}{3} {L}_{x} and \frac{1}{3} {L}_{y} < \frac{Σ {y}_{i} {A}_{i}}{Σ {A}_{i}} < \frac{2}{3} {L}_{y}$$

Particularly, when a semiconductor IC is mounted on the PCB pillars 222 and the connecting pillars 233 formed on the upper portion of the PCB layer 220, the center of gravity of the center portion of the mounted semiconductor IC needs to satisfy the above equations, and this may prevent the semiconductor IC and the PCB pillars 222 and the connecting pillars 233 formed on the upper portion of the PCB layer 220 from slipping because, during a flip chip process related to the upper portion of the PCB layer 220, the semiconductor IC can remain horizontal without sloping in one direction. Consequently, stability can be secured during the flip chip process.

Hereinafter, the structure of electric connection between the PCB pillars 222 and the connecting pillars 233 formed on the upper portion of the PCB layer 220 and the second die 120 will be described in more detail with reference to FIG. 4. For convenience of description, the chip connection member 121 of the second die 120 illustrated in FIG. 2 is not illustrated in FIG. 4.

In the illustrated embodiment, first connecting members B1 may be disposed between the lower surface of the second die 120 and upper portions of the PCB pillars 222. Second connecting members B2 may be disposed between the lower surface of the second die 120 and upper portions of the connecting pillars 233. Particularly, the first connecting members B1 and the second connection members B2 may be disposed on chip connection portions 121a (refer to FIG. 2) of the second die 120, respectively.

The first connecting members B1 and the second connection members B2 may include a conductive material. Accordingly, the PCB pillars 222 and the connecting pillars 233 may be electrically connected to the second die 120.

In the illustrated embodiment, the diameter G1 of the first connecting members B1 and the diameter G2 of the second connecting members B2 are designed differently, considering that the interval between the PCB pillars 222 is different from that between the connecting pillars 233.

In the illustrated embodiment, the diameter G1 of the first connecting members B1 may be larger than the diameter G2 of the second connecting members B2. A flip chip process may be performed with the height T1 of the first connecting members B1 and the height T2 of the second connecting members B2 substantially identical, thereby preventing the second die 120 from slipping or sloping, which could otherwise occur when mounting a second die 120 on the PCB pillars 222 and the connecting pillars 233.

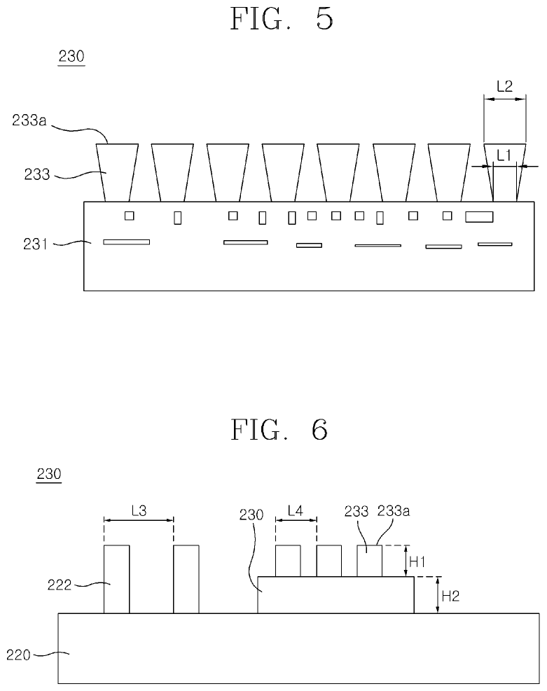

Hereinafter, the connecting structure 230 will be described in more detail with reference to FIG. 5.

As described above, connecting pillars 233 may be formed on the upper surface of the connecting structure 230.

In the illustrated embodiment, assuming that the width of the lower end of the connecting pillars 233 is a first width L1, and the width of the upper end thereof is a second width L2, the second width L2 is formed to be larger than the first width L1. That is, the connecting pillars 233 extend upwards from the upper surface of the connecting structure 230 so as to have an increasing horizontal width.

Accordingly, the sectional area in which the connecting pillars 233 abut the second die 120 may further increase due to structural characteristics. Additionally, connection between the second die 120 and the connecting structure 230 and alignment of the second die 120 are also facilitated.

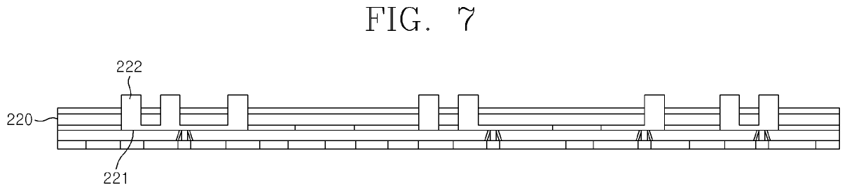

Hereinafter, the connecting structure 230 according to another embodiment will be described with reference to FIG. 6.

The present embodiment includes PCB pillars 222 formed on the upper portion of the PCB layer 220, a connecting structure 230, and connecting pillars 233.

Connecting pillars 233 are formed on the upper end of the connecting structure 230 at a height smaller than that of the PCB pillars 222, and respective upper ends of the connecting pillars 233 are positioned on a straight line horizontally.

The interval L3 is defined as the sum of the horizontal thickness of each PCB pillar 222 and the interval between two PCB pillars 222 adjacent to each other horizontally. The interval L4 is defined as the sum of the horizontal thickness of each connecting pillar 233 and the interval between two adjacent connecting pillars 233 adjacent to each other horizontally.

In addition, the first height H1 is defined as the height of the connecting pillars 233 formed on the connecting structure 230, and the second height H2 is defined as the height of the connecting structure 230.

In an embodiment, the sum of the first height H1 and the second height H2 may be smaller than or equal to the third interval L3.

In an embodiment, the first height H1 may be smaller than the interval L4.

Particularly, the second height H2 may be 30 μm-100 μm. The first height H1 may correspond to 50-150% of the second height H2. The first height H1 may be 15 μm-150 μm.

Consequently, the sum of the first height H1 and the second height H2 may be 45 μm-250 μm. The third interval L3 may be 45 μm-250 μm. In addition, the fourth interval L4 may be smaller than 150 μm.

As described above, the semiconductor package 1 according to the present disclosure can prevent the second die 120 from slipping or sloping more effectively by designing the height, thickness, and interval between the PCB pillars 222, the connecting structure 230, and the connecting pillars 233 according to the above-described relation equations.

Components of the semiconductor package 1 according to the present disclosure and coupling relation therebetween have been described above. Hereinafter, a method for manufacturing a semiconductor package 1 according to the present disclosure will be described with reference to FIG. 7 to FIG. 11.

Firstly, a PCB pillar 222 is provided on a PCB layer 220. The PCB pillar 222 is formed to extend upwards from a circuit 221 of the PCB layer 220 (refer to FIG. 7).

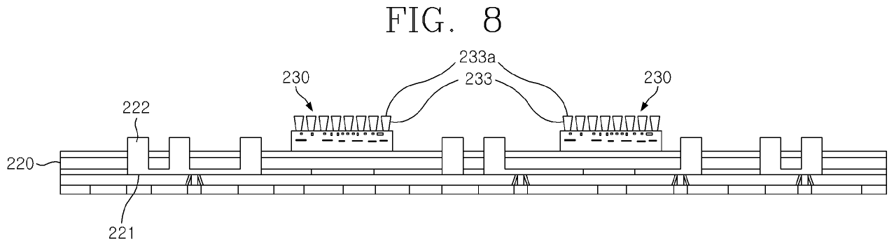

Next, a connecting structure 230 is prepared (refer to FIG. 8). Before the connecting structure 230 is installed on the PCB layer, a connecting pillar 233 is formed on the upper surface of the connecting structure 230. The connecting pillar 233 is formed on the upper surface of the connecting structure 230 so as to extend upwards with an increasing horizontal width. The completed connecting structure 230 is installed between two different PCB pillars 222.

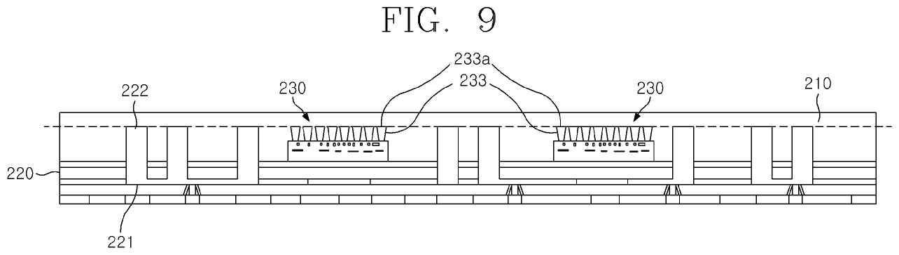

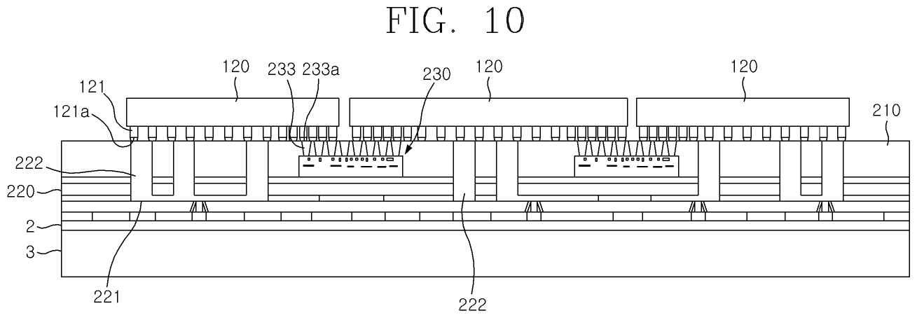

After completing installation of the connecting structure 230, a mold 210 is formed on the PCB layer 220 and the connecting structure 230 (refer to FIG. 9). A part of the mold 210 is partially removed by a grinding process. Dotted lines in FIG. 9 indicate grinding reference lines.

In the grinding process, the upper end of the connecting pillar 233 of the connecting structure 230 and the upper end of the PCB pillar 222 of the PCB layer 220 are ground together. Accordingly, the upper end of the PCB pillar 222 and the upper end of the connecting pillar 233 are exposed to the outside, and the upper end of the PCB layer 220 and the upper end of the connecting structure 230 230 are positioned on a straight line horizontally.

Therefore, a bridge connection portion 233a may be formed to be connected to the second die 120 without a separate wiring process. Consequently, manufacturing processes of the semiconductor package 1 can be further simplified.

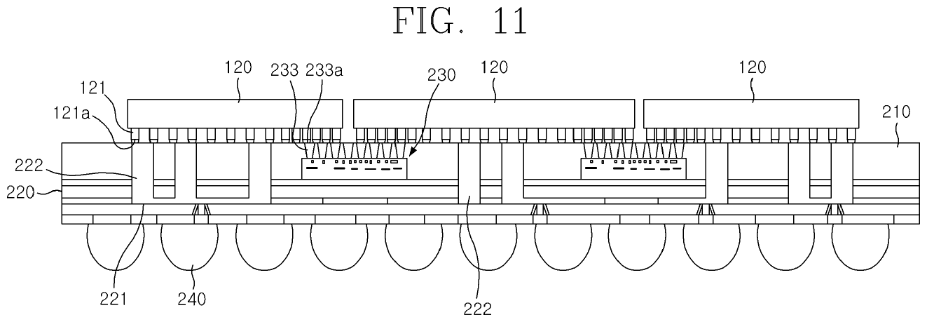

Lastly, the PCB layer 220 and the connecting structure 230 are connected to a second die 120 (refer to FIG. 10). A first die 110 and a second die 120 may be mixed and installed on the upper ends of the PCB layer 220 and the connecting structure 230. In addition, the first die 110 and the second die 120 are installed to directly contact the connecting structure 230, respectively, conductively.

In an embodiment, the above process may be assisted by a release layer 2 and a carrier substrate 3.

If the PCB layer 220 is excessively thin and thus is difficult to handle, a carrier substrate 3 may be coupled to the lower surface of the PCB layer 220 to complement the same, however, the carrier substrate 3 needs to be separated after coupling of the second die 120, and a release layer 2 is additionally disposed between the lower surface of the PCB layer 220 and the carrier substrate 3 such that the carrier substrate 3 can be easily separated.

The release layer 2 and the carrier substrate 3 are removed after coupling of the second die 120 is completed, and are not included as components of the finished semiconductor package 1.

Additionally, an external connection member 240 may be applied to the lower surface of the PCB layer 220 (refer to FIG. 11).

Among various advantageous effects of the present disclosure, advantageous effects obtainable from the above-described aspects are as follows:

Firstly, a semiconductor package includes a first die and a second die formed by stacking multiple dies, and a printed circuit board (PCB) layer. In addition, the first die and the second die are arranged side by side horizontally.

A connecting structure is installed between the first and second dies and the PCB layer. The connecting structure is positioned between two different PCB pillars provided on the upper surface of the PCB layer.

Therefore, the connecting structure is not necessarily installed is not necessarily installed on the entire surface of the PCB layer, but is sufficiently installed on a part of the upper surface of the PCB overlapping the first die and the second die. This may further reduce the area of installation of the connecting structure, thereby decreasing the manufacturing cost of the connecting structure. Furthermore, the entire cost for manufacturing the semiconductor package may be decreased.

In addition, the reduced area of installation of the connecting structure, as described above, is advantageous for compactness of the connecting structure.

Therefore, as the connecting structure occupies a reduced space, it may become possible to implement the entire high-performance semiconductor package compact.

In addition, after a mold is coupled to the PCB on which the connecting structure is installed, the semiconductor package has a connection portion formed between the PCB and the connecting structure through a grinding process.

Therefore, no separate wiring process is necessary after mounting the second die. Consequently, the semiconductor package manufacturing process may be further simplified.

In addition, the semiconductor package further includes a heat dissipation die or an active die vertically overlapping at least two second dies, and a thermal interface material is disposed between the second dies and on upper surfaces of the first and second dies so as to dissipate heat generated by the second dies to the outside.

Therefore, heat generated by the second dies can be dissipated more easily, thereby preventing semiconductor chips from overheating. Moreover, any damage to the semiconductor package due to overheating can be prevented, and maintenance/repair costs incurred by such damage occurring can be avoided.

Although the present disclosure has been described above with reference to exemplary embodiments, the present disclosure is not limited to the configuration of the above-described embodiments.

In addition, the present disclosure may be variously modified and changed by a person skilled in the art to which the present disclosure pertains without deviating from the idea and scope of the present disclosure defined in the appended claims.

Furthermore, all or some of respective embodiments may be selectively combined and configured such that above embodiments can be variously modified.

What is claimed is:

1. A semiconductor package comprising:
a first die;
a second die arranged horizontally to the first die;
a printed circuit board (PCB) layer comprising a circuit and a PCB pillar extending upwards from the circuit so as to abut the first die or the second die; and
a connecting structure disposed on an upper surface of the PCB layer between two different PCB pillars and conductively connected to each of the first die and the second die.

2. The semiconductor package of claim 1, wherein a connecting pillar is formed on an upper surface of the connecting structure so as to extend upwards with an increasing horizontal width and to abut the first die or the second die.

3. The semiconductor package of claim 1, wherein the connecting structure has a sectional area formed to be smaller than the combined sectional area of the first die and the second die coupled to the connecting structure.

4. The semiconductor package of claim 1, wherein the connecting structure comprises a connecting pillar disposed on an upper surface of the connecting structure so as to abut the first die or the second die.

5. The semiconductor package of claim 4, wherein the sum of the height of the connecting structure and the height of the connecting pillar formed on the connecting structure is formed to be smaller than the sum of the horizontal thickness of the PCB pillars and the interval between two PCB pillars adjacent to each other horizontally.

6. The semiconductor package of claim 4, wherein the height of the connecting pillar formed on the connecting structure is formed to be smaller than the sum of the horizontal thickness of the connecting pillar and the interval between two connecting pillars adjacent to each other horizontally.

7. The semiconductor package of claim 4, wherein the height of the connecting pillar corresponds to 50-150% of the height of the connecting structure.

8. The semiconductor package of claim 1, wherein a connecting pillar is formed on an upper surface of the connecting structure so as to extend upwards and to abut the first die or the second die, and the connecting pillar and the PCB pillar have respective upper ends positioned on a straight line horizontally.

9. The semiconductor package of claim 1, wherein a plurality of second dies are arranged side by side horizontally, and the connecting structure has at least a part conductively connected to each of a plurality of different second dies.

10. The semiconductor package of claim 9, further comprising a heat dissipation die or an active die vertically overlapping at least two second dies.

11. The semiconductor package of claim 10, wherein the active die further comprises an electric connecting means provided on a lower portion thereof so as to be connected to the second die.

12. The semiconductor package of claim 10, further comprising a thermal interface material between the second die and the heat dissipation die or the active die and on upper surfaces of the first die and the heat dissipation die or the active die, respectively, so as to dissipate heat generated in the second die outwards.

13. The semiconductor package of claim 1, wherein a plurality of first dies are formed to be vertically stacked.

14. The semiconductor package of claim 1, wherein the connecting structure is made of a silicon wafer.

15. The semiconductor package of claim 1, wherein the connecting structure is made of an active die or an integrated passive device (IPD).

16. The semiconductor package of claim 1, wherein a plurality of PCB pillars and connecting pillars are disposed on an upper surface of the PCB layer to be spaced apart from each other,
the plurality of PCB pillars and connecting pillars are formed at an identical height, and
assuming that the PCB layer has a transverse length of Lx and has a longitudinal length of Ly, the PCB pillars and connecting pillars have transverse coordinates of xi and have longitudinal coordinates of yi, and pad area of the PCB pillars or connecting pillars formed and exposed on the PCB layer is Ai, equations
$$\frac{1}{3} {L}_{x} < \frac{Σ {x}_{i} {A}_{i}}{Σ {A}_{i}} < \frac{2}{3} {L}_{x} and \frac{1}{3} {L}_{y} < \frac{Σ {y}_{i} {A}_{i}}{Σ {A}_{i}} < \frac{2}{3} {L}_{y}$$
are both satisfied.

17. A semiconductor package manufacturing method comprising the steps of:
(a) forming a PCB pillar so as to extend upwards from a circuit of a PCB layer;
(b) installing a connecting structure between two different PCB pillars;
(c) forming a mold on the PCB layer and the connecting structure;
(d) grinding the mold such that the upper end of the PCB pillar and the upper end of a connecting pillar extending upwards from the connecting structure are exposed outwards; and
(e) installing a first die and a second die side by side horizontally on the upper end of the PCB layer and on the upper end of the connecting pillar such that each of the first die and the second die contact the connecting pillar conductively.

18. The semiconductor package manufacturing method of claim 17, wherein, prior to step (b), a step (b0) of forming the connecting pillar on the upper surface of the connecting structure so as to extend upwards with an increasing horizontal width is performed.

19. The semiconductor package manufacturing method of claim 17, wherein, after step (d) and prior to step (e), a step (e0) of coupling a release layer and a carrier substrate to the lower surface of the PCB layer is performed, and
after step (e), a step (e1) of removing the release layer and the carrier substrate is performed.

20. The semiconductor package manufacturing method of claim 17, wherein, after step (e), a step (f) of applying an external connection member to the lower surface of the PCB layer is performed.
